(19) United States
(12) Patent Application Publication
(10) Pub. No.: US 2024/0357751 A1
(43) Pub. Date: Oct. 24, 2024

(54) ELECTRONIC DEVICE

(71) Applicant: Advanced Semiconductor Engineering, Inc., Kaohsiung (TW)

(72) Inventors: Hsin-Yu CHEN, Kaohsiung (TW); Huei-Shyong CHO, Kaohsiung (TW); Shih-Wen LU, Kaohsiung (TW)

(73) Assignee: Advanced Semiconductor Engineering, Inc., Kaohsiung (TW)

(21) Appl. No.: 18/137,938

(22) Filed: Apr. 21, 2023

(51) Int. Cl. H05K 5/00; H05K 1/16; H05K 3/36; H05K 5/02

(52) U.S. Cl. CPC H05K 5/0021; H05K 1/162; H05K 1/165; H05K 3/36; H05K 5/0247

(57) ABSTRACT

An electronic device is disclosed. The electronic device includes a first circuit structure, a second circuit structure having a surface facing the first circuit structure, and a first electronic component disposed over the first circuit structure and supporting the second circuit structure. The electronic device also includes a second electronic component disposed adjacent to the second circuit structure and having a top surface at an elevation higher than the surface of the second circuit structure with respect to the first circuit structure.

### BACKGROUND

### 1. Field of the Disclosure

The present disclosure relates to an electronic device, and in particular to an electronic device having an active device and a passive device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a first circuit structure, a second circuit structure having a surface facing the first circuit structure, and a first electronic component disposed over the first circuit structure and supporting the second circuit structure. The electronic device also includes a second electronic component disposed adjacent to the second circuit structure and having a top surface at an elevation higher than the surface of the second circuit structure with respect to the first circuit structure.

In some arrangements, an electronic device includes a first circuit structure having a first surface and a side surface adjacent to the first surface, and a first electronic component disposed over the first surface of the first circuit structure. The electronic device also includes a second electronic component disposed adjacent to the side surface of the first circuit structure and configured to receive a first power from the first electronic component.

In some arrangements, an electronic device includes a first circuit structure, a second circuit structure disposed over the first circuit structure, and a power regulating device disposed over the second circuit structure. The power regulating device has a non-power circuit region and a power circuit region closer to a periphery of the power regulating device than the non-power circuit region

### BRIEF DESCRIPTION OF THE DRAWINGS

Aspects of some arrangements of the present disclosure are readily understood from the following detailed description when read with the accompanying figures. It should be noted that various structures may not be drawn to scale, and dimensions of the various structures may be arbitrarily increased or reduced for clarity of discussion.

FIG. 1A is a cross-section of an exemplary electronic device according to some arrangements of the present disclosure.

FIG. 1B is a top view of an exemplary part of an electronic device according to some arrangements of the present disclosure.

FIG. 1C is a top view of an exemplary part of an electronic device according to some arrangements of the present disclosure.

FIG. 1D is a bottom view of an exemplary part of an electronic device according to some arrangements of the present disclosure.

FIG. 2 is a cross-section of an exemplary electronic device according to some arrangements of the present disclosure.

FIG. 3 is a cross-section of an exemplary electronic device according to some arrangements of the present disclosure.

FIG. 4 is a cross-section of an exemplary electronic device according to some arrangements of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

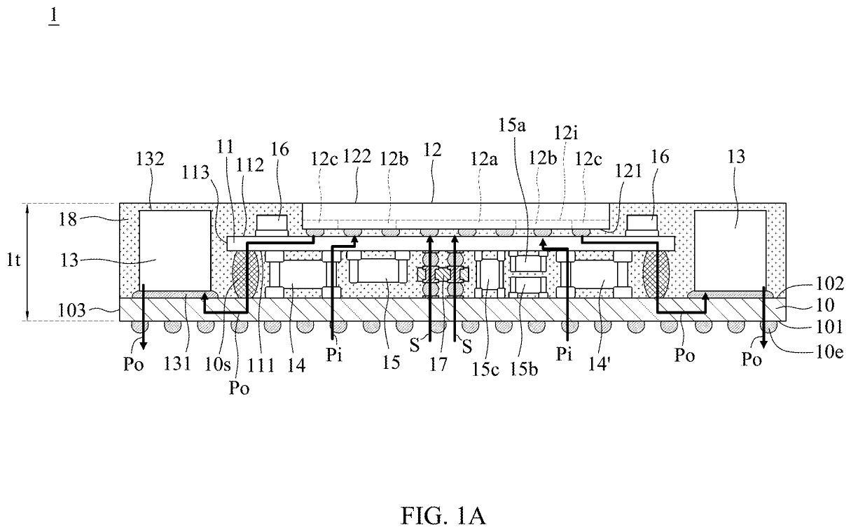

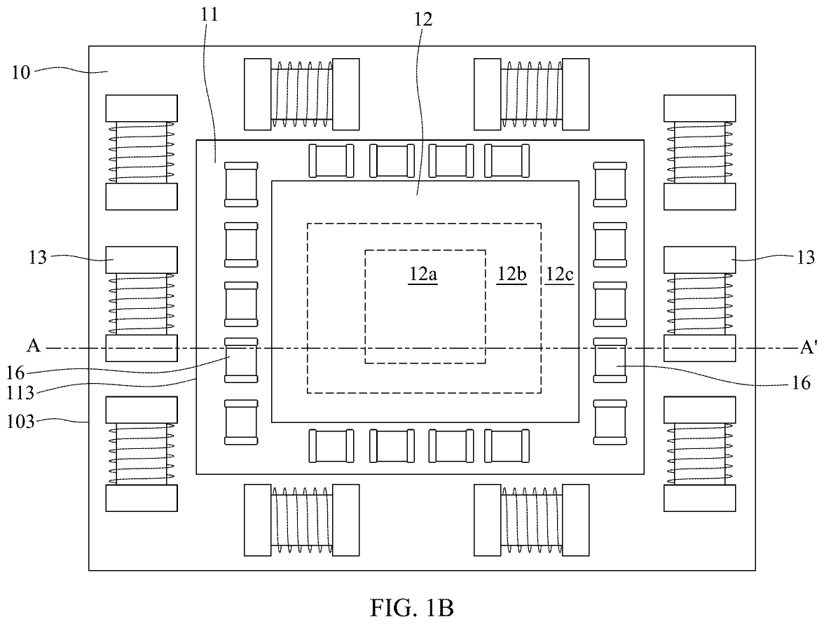

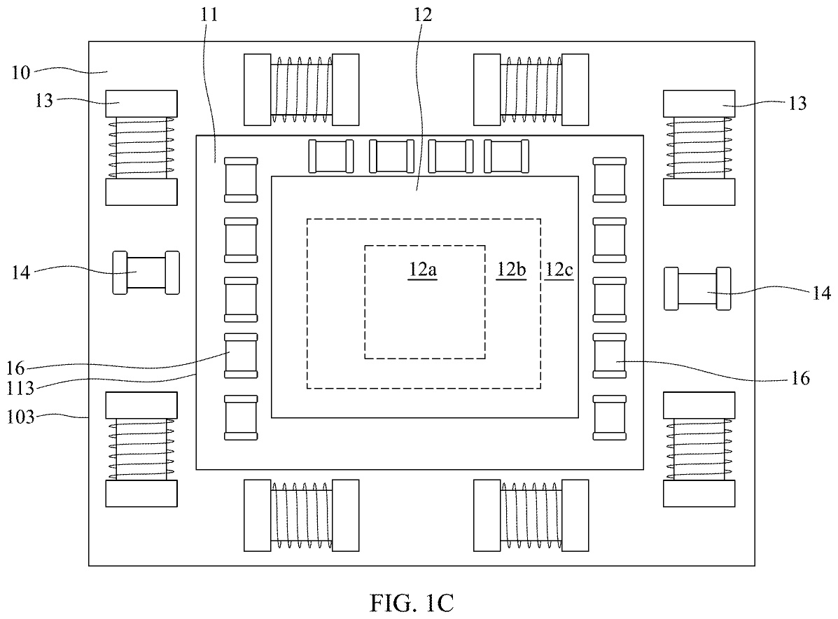

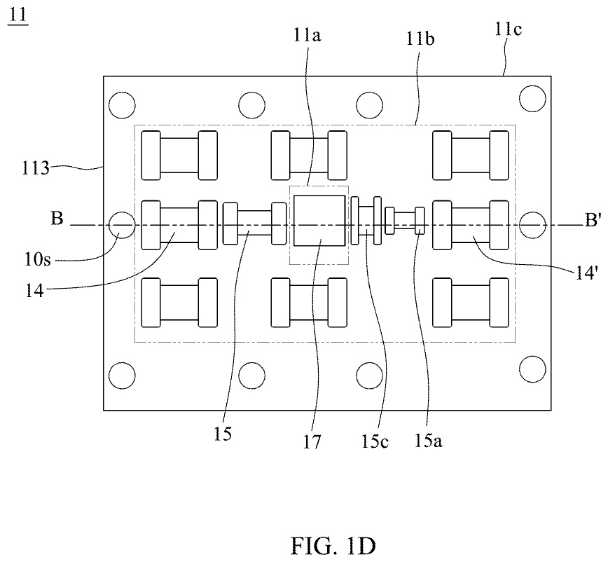

FIG. 1A is a cross-section of an exemplary electronic device 1 according to some arrangements of the present disclosure. In some arrangements, the electronic device 1 may include a package, such as a semiconductor device package. In some arrangements, the electronic device 1 may include carriers 10, 11, an active device 12, one or more passive devices 13, 14, 14′, 15, 15a, 15b, 15c, 16, a connection device 17, and an encapsulant 18.

In some arrangements, the carrier 10 may include, for example, a printed circuit board (PCB), such as a paper-based copper foil laminate, a composite copper foil laminate, or a polymer-impregnated glass-fiber-based copper foil laminate. In some arrangements, the carrier 10 may include a semiconductor substrate and may include silicon, germanium, or other suitable materials. In some arrangements, the carrier 10 may include an interconnection structure or a circuit structure, such as a redistribution layer (RDL) and/or a grounding element.

In some arrangements, the carrier 10 may include a surface 101, a surface 102 opposite to the surface 101, and a surface (or lateral surface) 103 extending between the surface 101 and the surface 102. The surface 101 may include the bottom surface of the carrier 10 and the surface 102 may include the top surface of the carrier 10. The surface 103 may include the outermost lateral surface of the carrier 10. For example, the surface 103 may include a boundary or an edge of the carrier 10.

The carrier 10 may include one or more conductive pads (not shown) in proximity to, adjacent to, or embedded in and exposed from the surface 101 and/or the surface 102 of the carrier 10. The carrier 10 may include a solder resist (not shown) over the surface 101 and/or the surface 102 of the carrier 10 to fully expose or to expose at least a portion of the conductive pads for electrical connections, including, for example, power path(s) (e.g., an input power path “Pi” and an output power path “Po”) and non-power path(s) (e.g., a non-power path “S”) in the electronic device 1.

As used herein, a power path may refer to a path dedicated to power supply connections. Additionally, a non-power path may refer to a path through which a non-power signal (or data) may be transmitted. A non-power signal may include analog signals, digital signals, clock signals or other electrical signals other than power signals.

In some arrangements, an electrical contact 10e may be disposed over the surface 101 of the carrier 10 and can provide electrical connections between the electronic device 1 and external components (e.g., external circuits or circuit boards). An electrical contact 10s may be disposed over the surface 102 of the carrier 10 and can provide electrical connections between the carrier 10 and the carrier 11. The electrical contact 10s may be disposed between the passive devices 13 and 14. In some arrangements, the electrical contact 10e and the electrical contact 10s may each include a connector, such as a metal block, a conductive pillar, a conductive via, a conductive wire, a solder ball, etc. In some arrangements, the solder ball may include a controlled collapse chip connection (C4) bump, a ball grid array (BGA) or a land grid array (LGA).

The carrier 11 may be disposed over the surface 102 of the carrier 10. Similar to the carrier 10, the carrier 11 may include a PCB, a semiconductor substrate. The carrier 11 may include an interconnection structure or a circuit structure, such as an RDL and/or a grounding element. The carrier 11 may be electrically connected to the carrier 10 through the electrical contact 10s, the passive devices 14, 15, and the connection device 17.

In some arrangements, the carrier 11 may include a surface 111, a surface 112 opposite to the surface 111, and a surface (or lateral surface) 113 extending between the surface 111 and the surface 112. The surface 111 may face the carrier 10. The surface 111 may include the bottom surface of the carrier 11 and the surface 112 may include the top surface of the carrier 11. The surface 113 may include the outermost lateral surface of the carrier 11. For example, the surface 113 may include a boundary or an edge of the carrier 11.

The surface 113 of the carrier 11 may be spaced apart from the surface 103 of the carrier 10. The surface 113 of the carrier 11 may be misaligned with the surface 103 of the carrier 10. The carrier 11 may cover the central portion of the carrier 10 and expose a periphery portion of the carrier 10. The carrier 11 may overlap the central portion of the carrier 10 in a direction substantially perpendicular to the surface 111 and/or the surface 112 of the carrier 11. The carrier 11 may overlap the central portion of the carrier 10 in a direction substantially perpendicular to the surface 101 and/or the surface 102 of the carrier 10. The passive device 13 may overlap the periphery portion of the carrier 10 in a direction substantially perpendicular to the surface 101 and/or the surface 102 of the carrier 10.

The carrier 11 may include one or more conductive pads (not shown) in proximity to, adjacent to, or embedded in and exposed from the surface 111 and/or the surface 112 of the carrier 11. The carrier 11 may include a solder resist (not shown) over the surface 111 and/or the surface 112 of the carrier 11 to fully expose or to expose at least a portion of the conductive pads for electrical connections, including, for example, the power path(s) and the non-power path(s) in the electronic device 1.

The active device 12 may be disposed over the surface 112 of the carrier 11. The active device 12 may be electrically connected to the carrier 11 by way of solder bonding, Cu-to-Cu bonding, wire-bonding, or hybrid bonding.

The active device 12 may cover the central portion of the carrier 11 and expose a periphery portion of the carrier 11. The active device 12 may overlap the central portion of the carrier 11 in a direction substantially perpendicular to the surface 111 and/or the surface 112 of the carrier 11. The passive device 16 may overlap the periphery portion of the carrier 11 in a direction substantially perpendicular to the surface 111 and/or the surface 112 of the carrier 11.

In some arrangements, the active device 12 may be circuits or circuit elements that rely on an external power supply to control or modify electrical signals. In some arrangements, the active device 12 may include a processor, a controller, a memory, or an input/output (I/O) buffer, etc. In some arrangements, the active device 12 may include a power regulating device or a power management integrated circuit (PMIC). In some arrangements, the active device 12 may include a voltage regulator, such as a linear regulator (which is configured to maintain a constant output voltage) or a switching regulator (which is configured to generate an output voltage higher than or lower than the input voltage). In some arrangements, the active device 12 may include a step-down (buck) converter, a step-up (boost) converter, an analog-to-digital converter, a digital-to-analog converter, an AC-DC converter, a DC-DC converter, other types of converters, or a combination thereof.

In some arrangements, the active device 12 may include a surface 121 facing the carrier 11 and a surface (or a top surface) 122 opposite to the surface 121. In some arrangements, the surface 121 may include an active surface and the surface 122 may include a backside surface or a rear surface. In some arrangements, a power signal and/or a non-power signal may be transmitted through the active surface (e.g., the surface 121) of the active device 12. For example, the input power path Pi, the output power path Po, and/or the non-power path S may pass through (or connect to) the active surface (e.g., the surface 121) of the active device 12.

In some arrangements, the active device 12 may include a circuit region 12i adjacent to the surface 121. In some arrangements, the circuit region 12i may include a non-power circuit region (or a signal circuit region) 12a, an input power circuit region 12b, and an output power circuit region 12c. The output power circuit region 12c may encircle or surround the input power circuit region 12b, and the input power circuit region 12b may encircle or surround the non-power circuit region 12a. The non-power circuit region 12a may be the central portion of the circuit region 12i of the active device 12. The input power circuit region 12b may be disposed between the non-power circuit region 12a and the output power circuit region 12c.

It should be noted that the boundaries of the non-power circuit region 12a, the input power circuit region 12b, and the output power circuit region 12c are for illustration purposes and are not intended to limit the present disclosure. The input power circuit region 12b may be physically connected with the non-power circuit region 12a and/or the output power circuit region 12c. In some arrangements, the input power circuit region 12b may be physically spaced apart from the non-power circuit region 12a and/or the output power circuit region 12c. For example, the input power circuit region 12b may not abut or adjoin the non-power circuit region 12a and/or the output power circuit region 12c.

The non-power circuit region 12a may be configured to transmit a non-power signal and/or to receive a non-power signal through the non-power path S. The input power circuit region 12b may be configured to receive an input power signal through the input power path Pi. The output power circuit region 12c may be configured to transmit an output power signal through the output power path Po.

In some arrangements, the non-power circuit region 12a may include a high-speed circuitry region and/or a high-density circuitry region. For example, the circuit density of the non-power circuit region 12a may be relatively higher than that of the other circuit regions (such as the input power circuit region 12b and the output power circuit region 12c) of the electronic device 1. For example, the line spacing and/or the pad pitch of the non-power circuit region 12a may be relatively narrower than that of the other circuit regions of the electronic device 1.

The passive device 13 may be disposed over the surface 102 of the carrier 10. The passive device 13 may be electrically connected to the active device 12 through the carrier 10 and the carrier 11.

The passive device 13 may be disposed closer to the surface 103 of the carrier 10 than the carrier 11. The passive device 13 may be disposed next to the carrier 11. A projection area of the passive device 13 on the carrier 10 and a projection area of the carrier 11 on the carrier 10 may not overlap. The surface 113 of the carrier 11 may face the passive device 13. The surface 113 of the carrier 11 may be spaced apart from the passive device 13. The surface 113 of the carrier 11 may overlap the passive device 13 in a direction substantially perpendicular to the surface 113 of the carrier 11. The surface 113 of the carrier 11 may overlap the passive device 13 in a direction substantially parallel with the surface 111 and/or the surface 112 of the carrier 11.

The passive device 13 may extend from an elevation lower than the surface 111 of the carrier 11 to an elevation higher than the surface 112 of the carrier 11. The passive device 13 may include a surface (or a bottom surface or a lower surface) 131, and a surface (or a top surface or an upper surface) 132 opposite to the surface 131 and facing away from the carrier 10. The surface 131 may be at an elevation lower than the surface 111 of the carrier 11 with respect to the surface 102 of the carrier 10. The surface 132 may be at an elevation higher than the surface 112 of the carrier 11 with respect to the surface 102 of the carrier 10.

The passive devices 14, 14′, 15, 15a, 15b, and 15c may each be disposed between the carrier 10 and the carrier 11. The passive device 14 may be disposed over the carrier 10 and support the carrier 11. The passive device 14 may be disposed under the carrier 11. An elevation of the passive device 14 may be lower than an elevation of the passive device 13 with respect to the carrier 11. A thickness of the passive device 14 may be substantially equal to the distance between the carrier 10 and the carrier 11.

The passive device 14′ may be disposed over the carrier 10 and support the carrier 11. The passive device 14′ may be disposed under the carrier 11. An elevation of the passive device 14′ may be lower than an elevation of the passive device 13 with respect to the carrier 11. A thickness of the passive device 14′ may be substantially equal to the distance between the carrier 10 and the carrier 11.

The passive device 15 may be disposed over the surface 111 of the carrier 11 and spaced apart from the carrier 10. The passive device 15 may be disposed under the carrier 11. An elevation of the passive device 15 may be lower than an elevation of the passive device 13 with respect to the carrier 11.

The passive device 15c may be disposed over the carrier 10 and support the carrier 11. The passive device 15c may be disposed under the carrier 11. An elevation of the passive device 15c may be lower than an elevation of the passive device 13 with respect to the carrier 11. A thickness of the passive device 15c may be substantially equal to the distance between the carrier 10 and the carrier 11.

The passive device 15a may be disposed over the surface 111 of the carrier 11 and spaced apart from the carrier 10. The passive device 15a may be disposed under the carrier 11. An elevation of the passive device 15a may be lower than an elevation of the passive device 13 with respect to the carrier 11.

The passive device 15b may be disposed over the surface 102 of the carrier 10 and spaced apart from the carrier 11. The passive device 15b may be disposed under the carrier 11. An elevation of the passive device 15b may be lower than an elevation of the passive device 13 with respect to the carrier 11. The passive device 15b may overlap the passive device 15a in a direction substantially perpendicular to the surface 111 and/or the surface 112 of the carrier 11. In some arrangements, the passive device 15b may be electrically connected to the passive device 15a to provide an electrical connection between the carrier 10 and the carrier 11.

The passive devices 14, 14′, 15, and 15c may each be electrically connected between the carrier 10 and the carrier 11. The passive devices 14 and 15 may each be electrically connected to the active device 12 through the carrier 11.

The passive device 16 may be disposed over the surface 112 of the carrier 11. The passive device 16 may be electrically connected to the active device 12 through the carrier 11.

In some arrangements, the passive devices 13, 14, 14′, 15, 15a, 15b, 15c, and 16 may each be circuits or circuit elements that do not need an external power source to function and do not provide electrical gain. In some arrangements, the passive devices 13, 14, 14′, 15, 15a, 15b, 15c, and 16 may each include an inductance device (or an inductor) or a capacitance device (or a capacitor). Other examples of passive devices may include, for example, resistors, diodes, fuses or antifuses, etc., which may be included along with the inductance device(s) and the capacitance device(s) in any combination.

The connection device 17 may be disposed between the carrier 10 and the carrier 11. The connection device 17 may be electrically connected between the carrier 10 and the carrier 11. The connection device 17 may include an interconnection structure, an interposer, or a substrate interposer.

In some arrangements, the connection device 17 may be present in the non-power path(s) in the electronic device 1. For example, the carrier 10 may have a connector or terminal (such as one or more of the electrical contacts 10e) configured to be electrically connected with a control source or a control signal supply (not illustrated in the figures).

The carrier 10, the connection device 17, and the carrier 11 may be configured to provide, define, construct, or establish the non-power path S between the control signal supply and the active device 12. The active device 12 may receive the non-power signal (or data). In some arrangements, the non-power signal (or data) may affect the control function request by a user. The non-power signal (or data) may be transmitted or conducted through the non-power circuit region (or the signal circuit region) 12a.

In some arrangements, the connection device 17 may be disposed below the non-power circuit region 12a of the active device 12. In some arrangements, the connection device 17 may be disposed closer to the center (or the central portion) of the active device 12 than any one of the passive devices 13, 14, 15, and 16. In some arrangements, the connection device 17 may overlap the non-power circuit region 12a of the active device 12 in a direction substantially perpendicular to the surface 121 and/or the surface 122 of the active device 12. In some arrangements, the connection device 17 may be disposed closer to the center (or the central portion) of the carrier 11 than any one of the passive devices 13, 14, 14′, 15, 15a, 15b, 15c, and 16. As such, the non-power path S can be shorter. In some arrangements, the non-power path S defined by the carrier 10, the connection device 17, and the carrier 11 may be substantially perpendicular to the surface 121 and/or the surface 122 of the active device 12. In some arrangements, the non-power path S defined by the carrier 10, the connection device 17, and the carrier 11 may include the shortest vertical distance between the surface 101 of the carrier 10 and the surface 112 of the carrier 11. For example, the non-power signal (or data) may be transmitted vertically from the surface 101 of the carrier 10 to the surface 112 of the carrier 11 without being transmitted horizontally.

In some arrangements, the passive devices 13, 14, 14′, 15, 15a, 15b, 15c, and 16 may be present in the power path(s) in the electronic device 1. For example, the carrier 10 may have a connector or terminal (such as one or more of the electrical contacts 10e) configured to be electrically connected with a power source or a power supply (not illustrated in the figures).

The carrier 10, the passive device 14, and the carrier 11 may be configured to provide, define, construct, or establish the input power path Pi between the power supply and the active device 12. In some arrangements, the input power from the power supply may be transmitted or conducted to the active device 12 through the carrier 10, the passive device 14, and the carrier 11 sequentially. In some arrangements, the passive device 14 may function as a voltage stabilizer. In some arrangements, a terminal of the passive device 14, the passive device 14′, and/or the passive device 15c may be a part of the input power path Pi.

The active device 12 may receive the input power, regulate the input power, and provide an output power (or a regulated power). The input power may be transmitted or conducted through the input power circuit region 12b, and the output power may be transmitted or conducted through the output power circuit region 12c.

The carrier 11, the electrical contact 10s, the passive device 13, and the carrier 10 may be configured to provide, define, construct, or establish the output power path Po between the active device 12 and an external component. In some arrangements, the output power from the active device 12 may be transmitted or conducted to the passive device 13 through the carrier 11, the electrical contact 10s, and the carrier 10 sequentially. In some arrangements, the passive device 13 may be directly connected with the carrier 11 through the electrical contact 10s and the carrier 10. In some arrangements, as mentioned, the electrical contact 10s may include a connector, such as a metal block, a conductive pillar, a conductive via, a conductive wire, a solder ball, etc. In some arrangements, the electrical contact 10s may include a zero-ohm link or zero-ohm resistor.

In some arrangements, there is no other passive device or active device connected between the active device 12 and the passive device 13 in series. As such, the output power path Po can be shorter than if there was another passive device or active device connected between the active device 12 and the passive device 13 in series. The voltage drop of the output power path Po can be decreased.

In some arrangements, one or more passive devices (such as the passive devices 15 and 16) may also be present in the output power path Po. For example, the passive device 15 may have one end connected to the passive device 13 and the external component, and another end connected to ground. In some arrangements, the passive devices 15 and 16 may function as filter capacitors. In some arrangements, the number and the location of the passive devices are not limited thereto, and there may be any number of the passive devices in the electronic device 1 depending on design requirements. For example, the passive devices 16 may also be disposed between the carrier 10 and the carrier 11.

In some arrangements, the output power path Po may extend from the central portion of the carrier 10 to the periphery portion of the carrier 10 to connect to the passive device 13. For example, the output power path Po may extend from a location under the carrier 11 to a location not covered by the carrier 11. For example, the output power path Po may exceed over the surface 113 of the carrier 11 from the cross-section in FIG. 1A.

In some arrangements, for the passive devices (e.g., the passive devices 14, 14′, 15, 15a, 15b, and 15c) between the carrier 10 and the carrier 11, the larger passive device is disposed closer to the passive device 13 (or to the surface 113 of the carrier 11) than the smaller one. For example, a dimension (such as a width, a length, a thickness, etc.) of the passive device 14 may be greater than a dimension of the passive device 15. Therefore, the passive device 14 may be disposed closer to the passive device 13 (or to the surface 113 of the carrier 11) than the passive device 15 is.

The largest passive device(s) (e.g., the passive device(s) 14) between the carrier 10 and the carrier 11, the surface 102 of the carrier 10, and the surface 111 of the carrier 11 may together define a space for accommodating other passive devices smaller than the largest passive device(s). For example, the passive device 15 may be disposed in the space. For example, the passive device 15 may be disposed between the passive device 14 and the connection device 17. As such, the electronic device 1 can be further miniaturized.

In some arrangements, the component(s) (e.g., the electrical contact 10s, the passive device 13, and the passive device 16) for providing the output power path Po may be disposed closer to the surface 103 of the carrier 10 than the component(s) (e.g., the passive device 14) for providing the input power path Pi are. In some arrangements, the component(s) (e.g., the electrical contact 10s, the passive device 13, and the passive device 16) for providing the output power path Po may be disposed closer to the surface 113 of the carrier 11 than the component(s) (e.g., the passive device 14) for providing the input power path Pi are. As such, the output power path Po can be closer to the output power circuit region 12c of the active device 12 and thus can be shorter. The voltage drops of the output power path Po can be decreased.

However, since the largest passive device(s) (e.g., the passive device 14) between the carrier 10 and the carrier 11 is to be disposed closer to the passive device 13 (or to the surface 113 of the carrier 11) than the smaller one(s), some of the component(s) (e.g., the passive device 15) for providing the output power path Po may be disposed in the space defined by the passive device 14, the carrier 10, and the carrier 11 to improve space utilization. Therefore, some of the component(s) (e.g., the passive device 15) for providing the output power path Po may be disposed farther from the surface 103 of the carrier 10 than the component(s) (e.g., the passive device 14) for providing the input power path Pi are. Therefore, some of the component(s) (e.g., the passive device 15) for providing the output power path Po may be disposed farther from the surface 113 of the carrier 11 than the component(s) (e.g., the passive device 14) for providing the input power path Pi are.

In some arrangements, the component(s) (e.g., the passive device 14) for providing the input power path Pi may be disposed closer to the central portion (e.g., the non-power circuit region 12a) of the active device 12 than the component(s) (e.g., the electrical contact 10s, the passive device 13, and the passive device 16) for providing the output power path Po are.

The encapsulant 18 may be disposed over the carrier 10 and covering or encapsulating the passive device 13. The surface 132 of the passive device 13 may be entirely covered by the encapsulant 18. The surface 122 of the active device 12 may not be covered by the encapsulant 18. For example, the surface 122 of the active device 12 may be exposed from the encapsulant 18. In some arrangements, the encapsulant 18 may also cover the passive devices 14, 15, and 16, and the connection device 17.

In some arrangements, the encapsulant 18 may also cover the surface 113 of the carrier 11. In some arrangements, a portion of the encapsulant 18 may be disposed between the surface 113 of the carrier 11 and the passive device 13. In some arrangements, the surface 103 of the carrier 10 may be exposed from the encapsulant 18. In some arrangements, the surface 103 of the carrier 10 may be aligned or substantially coplanar with a surface of the encapsulant 18.

In some arrangements, the encapsulant 18 may include an epoxy resin having fillers, a molding compound (e.g., an epoxy molding compound or another molding compound), a polyimide, a phenolic compound or material, a material with a silicone dispersed therein, or a combination thereof.

FIG. 1B is a top view of an exemplary part of an electronic device according to some arrangements of the present disclosure. In some arrangements, the electronic device 1 in FIG. 1A may have a top view as shown in FIG. 1B. In some arrangements, the electronic device in FIG. 1B along the line A-A′ may have a cross-section as shown in FIG. 1A.

From the top view perspective as shown in FIG. 1B, a surface area of the carrier 10 may be greater than a surface area of the carrier 11. A surface area of the carrier 11 may be greater than a surface area of the active device 12. A width of the carrier 10 may be greater than a width of the carrier 11. A width of the carrier 11 may be greater than a width of the active device 12.

The passive devices 13 may be disposed over the carrier 10 and around the carrier 11. The passive devices 13 may include inductance devices. The passive devices 13 may each include a conductive wire or coil winding around a core. The core may be orientated along the boundary of the carrier 11 to prevent mutual inductance among the passive devices 13. Therefore, the long axis of the passive device 13 may be orientated along the boundary of the carrier 11. For example, the long axis of the passive device 13 may be substantially parallel to the surface 113 of the carrier 11.

The passive devices 16 may be disposed over the carrier 11 and around the active device 12. The passive devices 16 may be disposed adjacent to the active device 12 to decrease the direct current (DC) resistance. However, the locations of the passive devices 16 are not limited thereto. For example, the passive devices 16 may be disposed between the carrier 10 and the carrier 11. For example, the passive devices 16 may be disposed between the passive device 14 and the connection device 17 in FIG. 1A.

FIG. 1C is a top view of an exemplary part of an electronic device according to some arrangements of the present disclosure. The top view in FIG. 1C is similar to the top view in FIG. 1B, with differences therebetween as follows.

The largest passive device(s) (e.g., the passive device 14) between the carrier 10 and the carrier 11 in FIG. 1A may be disposed over the carrier 10 and around the carrier 11. The passive device 14 may be disposed closer to the surface 103 of the carrier 10 than the carrier 11.

The passive device 14 may be disposed next to the carrier 11. A projection area of the passive device 14 on the carrier 10 and a projection area of the carrier 11 on the carrier 10 may not overlap. The surface 113 of the carrier 11 may face the passive device 14. The surface 113 of the carrier 11 may be spaced apart from the passive device 14. The surface 113 of the carrier 11 may overlap the passive device 14 in a direction substantially perpendicular to the surface 113 of the carrier 11. The surface 113 of the carrier 11 may overlap the passive device 14 in a direction substantially parallel with the surface 111 and/or the surface 112 of the carrier 11.

In some arrangements, the passive devices 14 may be the largest capacitance devices in the electronic device and the passive devices 13 may be the largest inductance devices in the electronic device. By disposing the passive devices 14 and the passive devices 13 over the carrier 10 and around the carrier 11, the electronic device can be further miniaturized. For example, a dimension (such as thickness and/or height) It of the electronic device 1 in FIG. 1A can be further reduced.

FIG. 1D is a bottom view of an exemplary part of an electronic device according to some arrangements of the present disclosure. In some arrangements, the electronic device 1 in FIG. 1A may have a bottom view as shown in FIG. 1D. In some arrangements, the electronic device in FIG. 1D along the line B-B′ may have a cross-section as shown in FIG. 1A.

From the bottom view as shown in FIG. 1D, the carrier 11 may include a non-power circuit region (or a signal circuit region) 11a, an input power circuit region 11b, and an output power circuit region 11c. The location of the non-power circuit region 11a, the location of the input power circuit region 11b, and the location of the output power circuit region 11c may be respectively corresponding to the location of the non-power circuit region 12a, the location of the input power circuit region 12b, and the location of the output power circuit region 12c of the active device 12 shown in FIG. 1A.

The output power circuit region 11c may encircle or surround the input power circuit region 11b, and the input power circuit region 11b may encircle or surround the non-power circuit region 11a. The non-power circuit region 11a may be the central portion of the carrier 11. The input power circuit region 11b may be disposed between the non-power circuit region 11a and the output power circuit region 11c.

It should be noted that the boundaries of the non-power circuit region 11a, the input power circuit region 11b, and the output power circuit region 11c are for illustration purposes and are not intended to limit the present disclosure. The input power circuit region 11b may be physically connected with the non-power circuit region 11a and/or the output power circuit region 11c. In some arrangements, the input power circuit region 11b may be physically spaced apart from the non-power circuit region 11a and/or the output power circuit region 11c. For example, the input power circuit region 11b may not abut or adjoin the non-power circuit region 11a and/or the output power circuit region 11c.

In some arrangements, the component(s) (e.g., the electrical contact 10s) for providing the output power path of the active device 12 (e.g., the output power path Po shown in FIG. 1A) may be disposed in the output power circuit region 11c. The component(s) (e.g., the passive device 14) for providing the input power path of the active device 12 (e.g., the input power path Pi shown in FIG. 1A) may be disposed in the input power circuit region 11b. The component(s) (e.g., the connection device 17) for providing the non-power path of the active device 12 (e.g., the non-power path S shown in FIG. 1A) may be disposed in the non-power circuit region 11a.

In some arrangements, as stated, the largest passive device(s) (e.g., the passive device 14) between the carrier 10 (shown in FIG. 1A) and the carrier 11 is to be disposed closer to the surface 113 of the carrier 11 than the smaller one(s) to further miniaturize the package size. The connection device 17 is disposed right below the non-power circuit region 12a of the active device 12 (shown in FIG. 1A) to reduce the non-power path of the active device 12 (e.g., the non-power path S shown in FIG. 1A). Therefore, some of the component(s) (e.g., the passive device 15) for providing the output power path of the active device 12 (e.g., the output power path Po shown in FIG. 1A) may be disposed in the input power circuit region 11b to make full use of the space between the passive device 14 and the connection device 17.

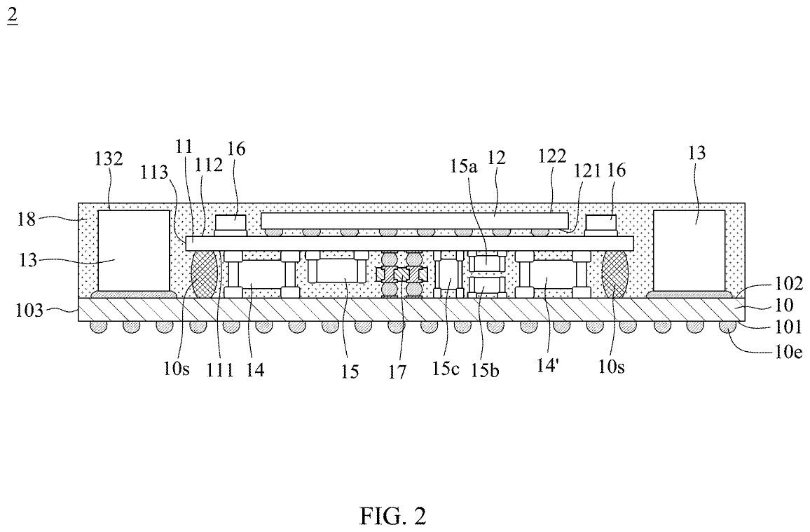

FIG. 2 is a cross-section of an exemplary electronic device 2 according to some arrangements of the present disclosure. The electronic device 2 is similar to the electronic device 1 in FIG. 1A except that the surface 122 of the active device 12 is covered or encapsulated by the encapsulant 18.

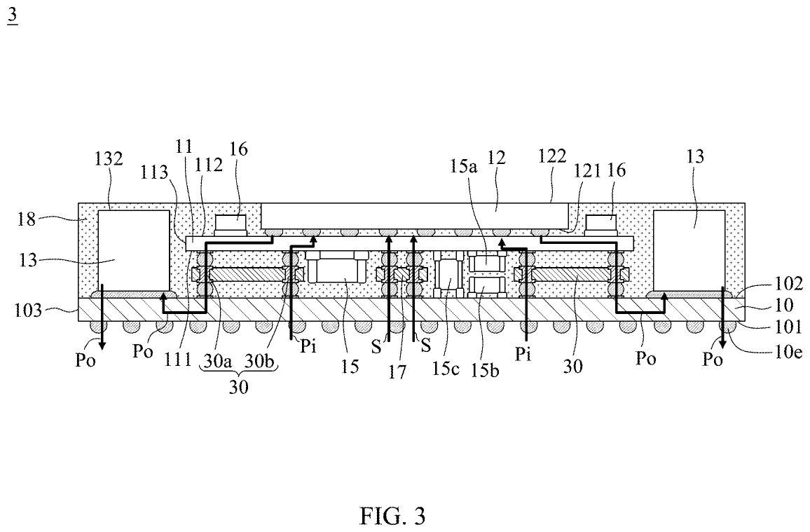

FIG. 3 is a cross-section of an exemplary electronic device 3 according to some arrangements of the present disclosure. The electronic device 3 is similar to the electronic device 1 in FIG. 1A, except that the electrical contacts 10s and the passive devices 14, 14′ in FIG. 1A are replaced with connection devices 30. The connection device 30 may include an interconnection structure or an interposer.

In some arrangements, the connection device 30 may include, for example, silicon (Si), glass or other suitable materials. In some arrangements, the connection device 30 may include connectors 30a and 30b, such as through-silicon vias. In some arrangements, the connectors 30a and 30b may each be electrically connected with the carrier 10 and the carrier 11 through an electrical contact, such as solder balls.

The carrier 10, the connector 30b of the connection device 30, and the carrier 11 may be configured to provide, define, construct, or establish the input power path Pi between an external power supply (not shown in the figures) and the active device 12. In some arrangements, the input power from the external power supply may be transmitted or conducted to the active device 12 through the carrier 10, the connector 30b of the connection device 30, and the carrier 11 sequentially.

The carrier 11, the connector 30a of the connection device 30, the passive device 13, and the carrier 10 may be configured to provide, define, construct, or establish the output power path Po between the active device 12 and an external component. In some arrangements, the output power from the active device 12 may be transmitted or conducted to the passive device 13 through the carrier 11, the connector 30a of the connection device 30, and the carrier 10 sequentially. In some arrangements, the passive device 13 may be directly connected with the carrier 11 through the connector 30a of the connection device 30 and the carrier 10. In some arrangements, the connector 30a of the connection device 30 may include a zero-ohm link or zero-ohm resistor.

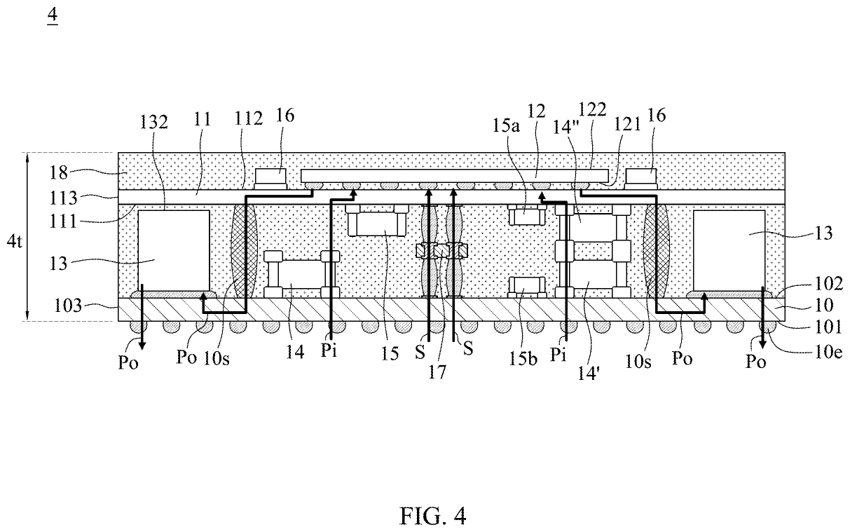

FIG. 4 is a cross-section of an exemplary electronic device 4 according to some arrangements of the present disclosure. The electronic device 4 is similar to the electronic device 1 in FIG. 1A, except that the passive device 13 is disposed between the carrier 11 and the carrier 10. The surface 132 of the passive device 13 is at an elevation lower than the surface 112 of the carrier 11 with respect to the surface 102 of the carrier 10. The passive device 14′ may overlap the passive device 14″ in a direction substantially perpendicular to the surface 111 and/or the surface 112 of the carrier 11. In some arrangements, the passive device 14′ may be electrically connected to the passive device 14″ to provide an electrical connection between the carrier 10 and the carrier 11.

In comparison with the electronic device 4 in FIG. 4, by disposing the passive device 13 over the carrier 10 and next to the carrier 11 as shown in FIG. 1A, the package size of the electronic device 1 in FIG. 1A can be miniaturized. For example, in comparison with a dimension (such as thickness and/or height) 4t of the electronic device 4, a dimension (such as thickness and/or height) It of the electronic device 1 is decreased by about 15%-20%.

According to some arrangements of the present disclosure, by disposing the passive device 13 over the carrier 10 and next to the carrier 11, the non-power path S, the input power path Pi, and the output power path Po can be shorter than if the passive device 13 is disposed between the carrier 11 and the carrier 10. All in all, package size can be miniaturized, signal propagation delay reduced, and electronic performance improved.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first circuit structure;
a second circuit structure having a surface facing the first circuit structure;
a first electronic component disposed over the first circuit structure and supporting the second circuit structure; and
a second electronic component disposed adjacent to the second circuit structure and having a top surface at an elevation higher than the surface of the second circuit structure with respect to the first circuit structure.

2. The electronic device of claim 1, further comprising:
a first connector connecting the first circuit structure to the second circuit structure, wherein the first connector is disposed between the first electronic component and the second electronic component.

3. The electronic device of claim 2, further comprising:
a third electronic component disposed over the second circuit structure and configured to electrically connect to the second electronic component by the first connector.

4. The electronic device of claim 3, further comprising:
a second connector connecting the first circuit structure to the second circuit structure, wherein the third electronic component is configured to electrically connect to first circuit structure by the first connector and the second connector respectively.

5. The electronic device of claim 4, wherein the first connector is configured to transmit a first signal, and the second connector is configured to transmit a second signal distinct from the first signal.

6. An electronic device, comprising:
a first circuit structure having a first surface and a side surface adjacent to the first surface;
a first electronic component disposed over the first surface of the first circuit structure; and
a second electronic component disposed adjacent to the side surface of the first circuit structure and configured to receive a first power from the first electronic component.

7. The electronic device of claim 6, wherein second electronic component is configured to receive the first power by the first circuit structure.

8. The electronic device of claim 7, wherein the first circuit structure has a second surface opposite to the first surface of the first circuit structure, and the second electronic component has a lower surface below the second surface of the first circuit structure and an upper surface above the first surface of the first circuit structure.

9. The electronic device of claim 6, further comprising:
a third electronic component disposed under the first circuit structure, wherein the first electronic component is configured to receive a second power from the third electronic component.

10. The electronic device of claim 9, further comprising:
a second circuit structure carrying the third electronic component, wherein the third electronic component supports the first circuit structure.

11. The electronic device of claim 10, wherein an elevation of the third electronic component is lower than an elevation of the second electronic component with respect to the second circuit structure.

12. The electronic device of claim 9, wherein the third electronic component includes a capacitor, and the second electronic component includes an inductor.

13. The electronic device of claim 9, wherein first electronic component has a circuit having a first region and a second region closer to a periphery of the first electronic component than the first region, wherein the first electronic component is configured to receive the second power through the first region, and wherein the first electronic component is configured to provide the first power to the second electronic component through the second region.

14. An electronic device, comprising:
a first circuit structure;
a second circuit structure disposed over the first circuit structure; and
a power regulating device disposed over the second circuit structure,
wherein the power regulating device has a non-power circuit region and a power circuit region closer to a periphery of the power regulating device than the non-power circuit region.

15. The electronic device of claim 14, wherein the non-power circuit region is encircled by the power circuit region.

16. The electronic device of claim 14, further comprising:
a connection device disposed between the first circuit structure and the second circuit structure, wherein the connection device is configured to transmit a signal or data to the non-power circuit region of the power regulating device.

17. The electronic device of claim 14, wherein the power circuit region comprises an input power circuit region and an output power circuit region, and wherein from a top view perspective, the input power circuit region is disposed between the output power circuit region and the non-power circuit region.

18. The electronic device of claim 17, further comprising:
a connector disposed between and electrically connected between the first circuit structure and the second circuit structure, wherein the connector is configured to construct an output power path for the output power circuit region of the power regulating device.

19. The electronic device of claim 18, further comprising:
an inductance device disposed adjacent to the second circuit structure, wherein an upper surface of the inductance device is at an elevation higher than a lower surface of the second circuit structure with respect to the first circuit structure, and wherein the inductance device is configured to receive an output power from the power regulating device through the output power path.

20. The electronic device of claim 17, further comprising:
a capacitance device disposed between the first circuit structure and the first circuit structure and configured to construct an input power path for the input power circuit region of the power regulating device.
